(19) United States
(12) Patent Application Publication
(10) Pub. No.: US 2026/0130083 A1
(43) Pub. Date: May 7, 2026

(54) DISPLAY APPARATUS

(71) Applicant: LG DISPLAY CO., LTD., SEOUL (KR)

(72) Inventors: Sookhee Jeong, Gimpo-si (KR); Seongjoo Lee, Goyang-si (KR); Yongmin Kim, Anyang-si (KR); JungSun Baek, Paju-si (KR); Yosup Sim, Seongnam-si (KR)

(21) Appl. No.: 19/334,383

(22) Filed: Sep. 19, 2025

(30) Foreign Application Priority Data
Nov. 4, 2024 (KR) 10-2024-0154265

(51) Int. Cl. H10K 59/35; H10K 59/122; H10K 59/80

(52) U.S. Cl. CPC H10K 59/352; H10K 59/122; H10K 59/80515

(57) ABSTRACT

A display apparatus includes a first area with first sub pixels and a second area outside the first area and including second sub pixels, an over coating layer including a base portion and protrusions that protrude from the base portion and each having an inclined side surface, first electrodes each of which is disposed in each of the first and second sub pixels, each first electrode covering the inclined side surface of the protrusion and the base portion, a bank layer on the protrusions and the first electrodes and exposing a part of the first electrodes, and an organic layer on the first electrodes and the bank layer. An inclination angle of the inclined side surface of the protrusion of the first sub pixels is larger than an inclination angle of the inclined side surface of the protrusion of the second sub pixels.

### CROSS-REFERENCE TO RELATED APPLICATIONS

Pursuant to 35 U.S.C. § 119(a), this application claims the benefit of an earlier filing date and right of priority to Korean Patent Application No. 10-2024-0154265 filed on Nov. 4, 2024, in the Korean Intellectual Property Office, the entire disclosure of which is incorporated herein by reference.

### TECHNICAL FIELD

The present disclosure generally relates to a display apparatus.

### BACKGROUND

In a full-scale information era, there has been rapid development of display apparatuses that visually express electrical information signals, with continued improvements in display apparatuses such as reduced thickness, lighter weights, and lower power consumption.

Among various display apparatuses, an organic light emitting display apparatus is a self-emitting display apparatus in which a separate light source is not necessary, which is different from the liquid crystal display apparatus. Organic light emitting display apparatuses can be manufactured to have a light weight and a small thickness. Further, such display apparatuses can be driven at a lower voltage, providing advantages not only in terms of power consumption, but also in terms of color implementation, a response speed, a viewing angle, and a contrast ratio (CR).

### SUMMARY

According to an aspect of the present disclosure, a display apparatus includes a substrate including a first area in which a plurality of first sub pixels is disposed and a second area outside a periphery of the first area and including a plurality of second sub pixels disposed therein, an over coating layer which is disposed on the substrate and includes a base portion and protrusions which protrude from the base portion, where each protrusion has an inclined side surface, a plurality of first electrodes each of which is disposed in each of the first and second sub pixels, and is disposed so as to cover the inclined side surface of the protrusion and the base portion, a bank layer disposed on a top surface of the protrusions and the first electrodes and exposes a part of the first electrodes disposed on the base portion, an organic layer disposed on the plurality of first electrodes and the bank layer, and a second electrode disposed on the organic layer. An inclination angle of the inclined side surface of the protrusion of the plurality of first sub pixels is larger than an inclination angle of the inclined side surface of the protrusion of the plurality of second sub pixels.

According to another aspect of the present disclosure, a display apparatus includes a substrate including a first area in which a plurality of first sub pixels is disposed and a second area outside a periphery of the first area and including a plurality of second sub pixels disposed therein, an over coating layer which is disposed on the substrate and includes a base portion and protrusions which protrude from the base portion, where each protrusion has an inclined side surface, a plurality of first electrodes each of which is disposed in each of the first and second sub pixels, and is disposed so as to cover the side surface of the protrusions and the base portion, a bank layer disposed on the protrusions and the first electrodes and exposes a part of the first electrodes disposed on the base portion, an organic layer disposed on the plurality of first electrodes and the bank layer, and a second electrode disposed on the organic layer. The protrusion protrudes with the same height from the base portion in each of the plurality of first sub pixels and the plurality of second sub pixels and an extending length in a direction parallel to the substrate of the side surface of the protrusion disposed in the plurality of first sub pixels is shorter than an extending length in the direction parallel to the substrate of the side surface of the protrusion disposed in the plurality of second sub pixels.

Other detailed matters of the example implementations are included in the detailed description and the drawings.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view of a display apparatus according to an example implementation of the present disclosure;

FIG. 2 is a cross-sectional view of a display apparatus taken along the line II-II′ of FIG. 1;

FIG. 3A is an enlarged cross-sectional view of one sub pixel disposed in a first area of a display apparatus according to an example implementation of the present disclosure;

FIG. 3B is a plan view for explaining an emission area and a non-emission area of one sub pixel disposed in a first area of a display apparatus according to an example implementation of the present disclosure;

FIG. 4 is a cross-sectional view of a display apparatus taken along the line IV-IV′ of FIG. 1;

FIG. 5A is an enlarged cross-sectional view of one sub pixel disposed in a second area of a display apparatus according to an example implementation of the present disclosure;

FIG. 5B is a plan view for explaining an emission area and a non-emission area of one sub pixel disposed in a second area of a display apparatus according to an example implementation of the present disclosure;

FIG. 5C is a cross-sectional view of one sub pixel disposed in a second area which is bent in a display apparatus according to an example implementation of the present disclosure; and

FIG. 6 is a cross-sectional view of a display apparatus taken along the line VI-VI′ of FIG. 1.

### DETAILED DESCRIPTION

Implementations of the present disclosure can provide a display apparatus in which a luminance difference between a curved portion or a bent portion and a flat portion is reduced to improve a display quality.

In some implementations, a display apparatus has an edge which is a curved portion or a bent portion, and a luminance difference between the curved portion or the bent portion and a flat portion is reduced to improve a display quality.

Such features can provide various technical benefits. For example, implementations disclosed herein can provide a display apparatus in which a production energy is reduced and process optimization is possible by performing processes for minimizing a luminance difference between a curved portion and a flat portion or a luminance difference between a bent portion and a flat portion using the same mask.

Objects of the present disclosure are not limited to the above-mentioned objects, and other objects, which are not mentioned above, can be clearly understood by those skilled in the art from the following descriptions.

According to some implementations of the present disclosure, an inclined surface of a first electrode disposed in a curved portion or a bent portion and an inclined surface of a first electrode disposed in a flat portion are configured to have different angles. This can, for example, improve the luminance degradation according to the viewing angle of the display apparatus.

According some implementations of the present disclosure, an angle of an inclined surface of a first electrode disposed in a curved portion or a bent portion and an angle of an inclined surface of a first electrode disposed in a flat portion are configured to be different using the same mask. This can, for example, reduce the number of masks and the number of processing processes that are used during manufacture.

The effects according to the present disclosure are not limited to the contents exemplified above, and more various effects are included in the present specification.

Advantages and characteristics of the present disclosure and a method of achieving the advantages and characteristics will be clear by referring to example implementations described below in detail together with the accompanying drawings. However, the present disclosure is not limited to the example implementations disclosed herein but will be implemented in various forms. The example implementations are provided by way of example only so that those skilled in the art can fully understand the disclosures of the present disclosure and the scope of the present disclosure.

The shapes, sizes, ratios, angles, numbers, and the like illustrated in the accompanying drawings for describing the example implementations of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as ‘including’, ‘having’, ‘consist of’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various implementations of the present disclosure can be partially or entirely adhered to or combined with each other and can be interlocked and operated in technically various ways, and the implementations can be carried out independently of or in association with each other.

Hereinafter, various implementations of the present disclosure will be described in detail with reference to accompanying drawings.

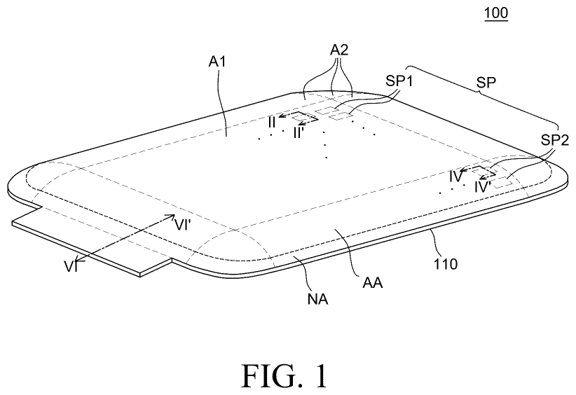

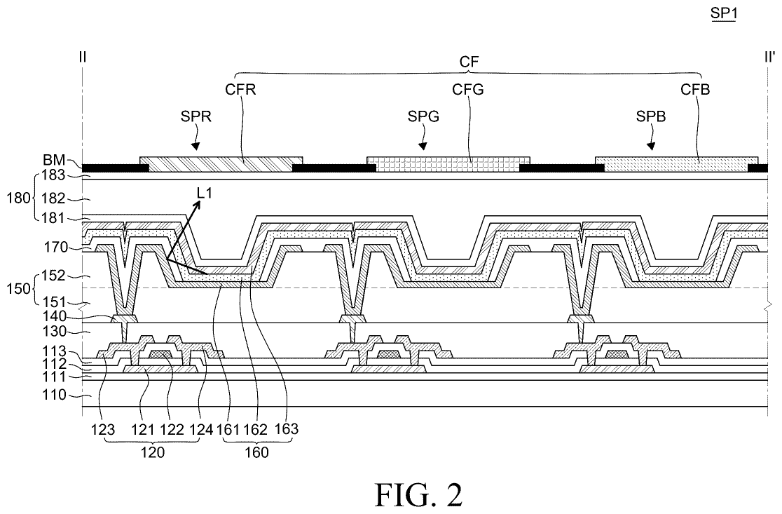

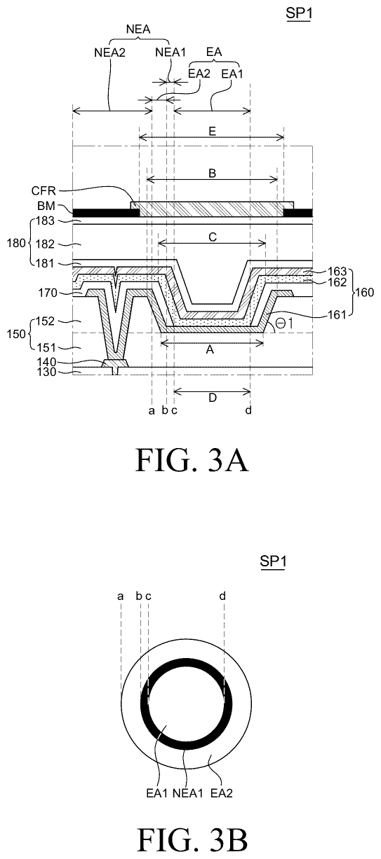

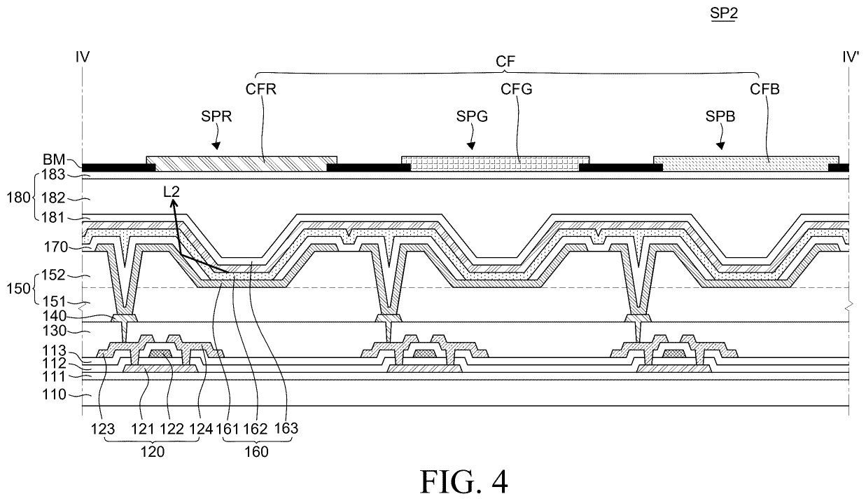

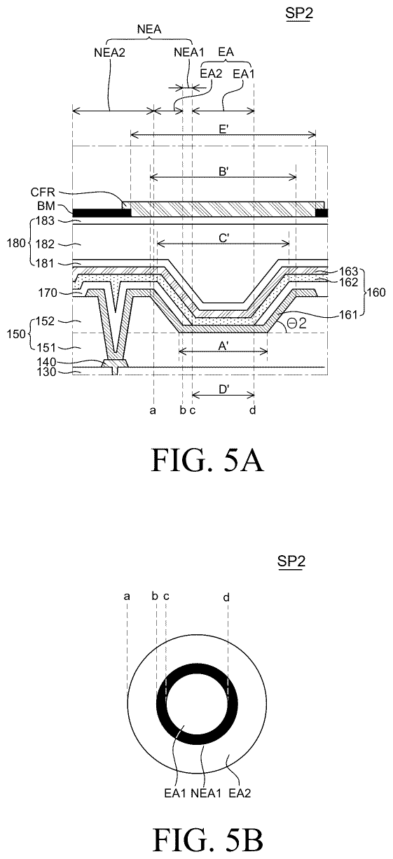

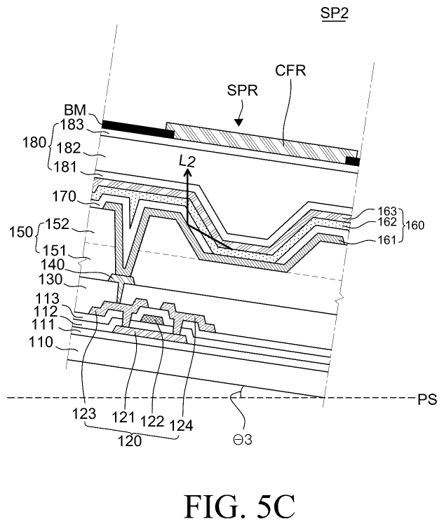

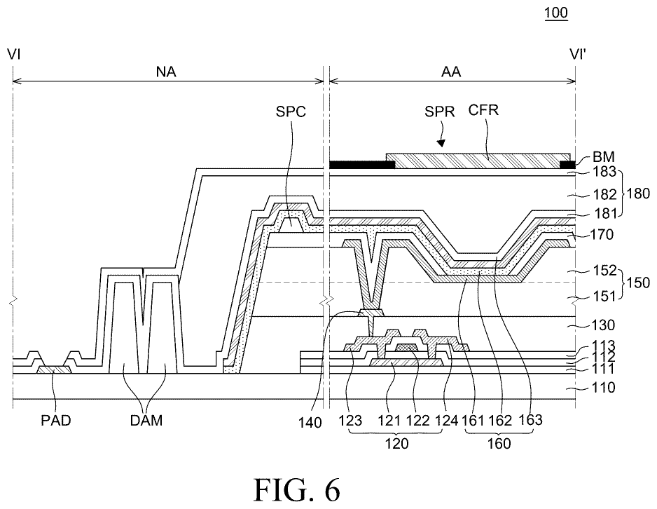

FIG. 1 is a perspective view of a display apparatus according to an example implementation of the present disclosure. FIG. 2 is a cross-sectional view of a display apparatus taken along the line II-II′ of FIG. 1. FIG. 3A is an enlarged cross-sectional view of one sub pixel disposed in a first area of a display apparatus according to an example implementation of the present disclosure. FIG. 3B is a plan view for explaining an emission area and a non-emission area of one sub pixel disposed in a first area of a display apparatus according to an example implementation of the present disclosure. FIG. 4 is a cross-sectional view of a display apparatus taken along the line IV-IV′ of FIG. 1. FIG. 5A is an enlarged cross-sectional view of one sub pixel disposed in a second area of a display apparatus according to an example implementation of the present disclosure. FIG. 5B is a plan view for explaining an emission area and a non-emission area of one sub pixel disposed in a second area of a display apparatus according to an example implementation of the present disclosure. FIG. 5C is a cross-sectional view of one sub pixel disposed in a second area which is bent in a display apparatus according to an example implementation of the present disclosure. FIG. 6 is a cross-sectional view of a display apparatus taken along the line VI-VI′ of FIG. 1. In FIG. 1, for the convenience of description, among various configurations of the display apparatus 100, only a substrate 110 is illustrated. In the meantime, dotted lines a to d of FIGS. 3A and 3B and dotted lines a to d of FIGS. 5A and 5B denote the same position.

Referring to FIGS. 1 to 6, the display apparatus 100 may include a substrate 110, a transistor 120, a first over coating layer 130, an auxiliary electrode 140, a second over coating layer 150, a light emitting diode 160, a bank layer 170, an encapsulation unit 180, a black matrix BM, and a color filter CF. The display apparatus 100 is implemented as atop emission type display apparatus.

Referring to FIGS. 1, 2, 4, and 6, the substrate 110 may support and protect several components of the display apparatus 100. The substrate 110 may be formed of a glass or a plastic material having flexibility. When the substrate 110 is formed of a plastic material, for example, the substrate may be formed of polyimide (PI), but it is not limited thereto.

The substrate 110 includes a first area A1 and a second area A2. In some implementations, the first area A1 is an area formed by a flat surface and the second area A2 is an area formed by a curved surface. The first area A1 may be a flat area and the second area A2 may be a curved area. The first area A1 is referred to as a flat portion and the second area A2 may be referred to as a curved portion or a bent portion. For example, the second area A2 is disposed in an upper portion, a lower portion, and both side portions of the first area A1 so that the farther from the first area A1, the larger the gradient. However, the present disclosure is not limited thereto and each of the second areas A2 disposed in the upper portion, the lower portion, and both side portions of the first area A1 may be disposed with different curvatures. Further, the second area A2 may be disposed on only one side surface of the first area A1 or may be disposed on all sides of the first area A1. For example, when the first area A1 has four sides, the second area A2 may be disposed in one or more sides, among four sides, or as illustrated in FIG. 1, the second area A2 may be disposed in all the four sides, but is not limited thereto.

The substrate 110 includes an active area AA and a non-active area NA. The active area AA and the non-active area NA may be disposed in the first area A1 and the second area A2 of the substrate 110, respectively.

The active area AA is an area in which an image is displayed in the display apparatus 100 and a display element and various driving elements for driving the display element are disposed in the active area AA. For example, the display element may be configured by a light emitting diode 160 including a first electrode 161, an organic layer 162, and a second electrode 163. Further, various driving elements for driving the display element, such as a thin film transistor 120, a capacitor, or a wiring line may be disposed in the active area AA.

A plurality of sub pixels SP may be included in the active area AA. The sub pixel SP is a minimum unit which configures a screen and each of the plurality of sub pixels SP may include a light emitting diode 160 and a driving circuit.

Referring to FIGS. 2 and 4, the plurality of sub pixels SP may emit light having different wavelengths. For example, the plurality of sub pixels SP may include at least one red sub pixel SPR, at least one green sub pixel SPG, and at least one blue sub pixel SPB, but, it is not limited thereto and the plurality of sub pixels SP may further include a white sub pixel.

Referring to FIG. 1, the plurality of sub pixels SP may include a first sub pixel SP1 and a second sub pixel SP2. The first sub pixel SP1 is a sub pixel disposed in the first area A1 of the active area AA and the second sub pixel SP2 is a sub pixel disposed in the second area A2 of the active area AA. That is, the first sub pixel SP1 may be disposed in the flat portion of the substrate 110 and the second sub pixel SP2 may be disposed in a curved portion of the substrate 110. The first sub pixel SP1 and the second sub pixel SP2 will be descried in detail with reference to FIGS. 4 to 5B.

The driving circuit of the sub pixel SP is a circuit for controlling the driving of the light emitting diode 160. For example, the driving circuit may be configured to include the thin film transistor 120 and the capacitor, but is not limited thereto.

Referring to FIGS. 1 and 6, the non-active area NA is an area where no image is displayed and various components for driving the plurality of sub pixels SP disposed in the active area AA may be disposed in the non-active area NA. For example, a driving IC which supplies a signal for driving the plurality of sub pixels SP, a flexible film, and a pad PAD for being connected to the driving IC and the flexible film may be disposed. However, the non-active area NA will be described below in more detail with reference to FIG. 6.

The non-active area NA may be an area which encloses the active area AA as illustrated in FIG. 1, but is not limited thereto. For example, the non-active area NA may be an area extending from one side of the active area AA.

The first sub pixel SP1 disposed in the first area A1 and the second sub pixel SP2 disposed in the second area A2 will be described with reference to FIGS. 2 to 4.

Referring to FIGS. 2 and 4, a buffer layer 111 is disposed on the substrate 110. The buffer layer 111 may improve adhesive strength between layers formed on the buffer layer 111 and the substrate 110 and block alkali components leaked from the substrate 110. The buffer layer 111 may be formed of a single layer of silicon nitride (SiNx) or silicon oxide (SiOx) or a multiple layer of silicon nitride (SiNx) and/or silicon oxide (SiOx), but is not limited thereto. The buffer layer 111 may be omitted based on a type and a material of the substrate 110 and a structure and a type of the thin film transistor 120.

The buffer layer 111 is disposed on the substrate 110. The buffer layer 111 may serve to improve adhesive strength between layers formed on the buffer layer 111 and the substrate 110 and block alkali components leaked from the substrate 110. The buffer layer 111 may be formed as a single layer of silicon nitride (SiNx) or silicon oxide (SiOx) or a multiple layer of silicon nitride (SiNx) and/or silicon oxide (SiOx), but is not limited thereto. The buffer layer 111 is not an essential component and may be omitted based on a type and a material of the substrate 110 and a structure and a type of the transistor 120.

The transistor 120 is disposed on the buffer layer 111. The transistor 120 may be used as a driving element which drives the light emitting diode 160 of the active area AA. The transistor 120 includes an active layer 121, a gate electrode 122, a source electrode 123, and a drain electrode 124. The transistor 120 illustrated in FIGS. 2 and 4 is a driving transistor and is a top gate type thin film transistor in which the gate electrode 122 is disposed on the active layer 121. However, it is not limited thereto and the transistor 120 may be implemented as a bottom gate type transistor.

The active layer 121 is disposed on the buffer layer 111. The active layer 121 is an area in which a channel is formed when the transistor 120 is driven. The active layer 121 may be formed of an oxide semiconductor or amorphous silicon (a-Si), polycrystalline silicon (poly-Si), or an organic semiconductor.

The gate insulating layer 112 is disposed on the active layer 121. The gate insulating layer 112 is a layer for electrically insulating the gate electrode 122 from the active layer 121 and may be formed of an insulating material. For example, the gate insulating layer 112 may be formed as a single layer of an inorganic material such as silicon nitride (SiNx) or silicon oxide (SiOx) or a multiple layer of inorganic materials such as silicon nitride (SiNx) and/or silicon oxide (SiOx), but it is not limited thereto.

In the gate insulating layer 112, a contact hole through which the source electrode 123 and the drain electrode 124 are in contact with a source region and a drain region of the active layer 121, respectively, is formed. The gate insulating layer 112 may be formed on the entire surface of the substrate 110 as illustrated in FIG. 2, or patterned to have the same width as the gate electrode 122, but is not limited thereto.

The gate electrode 122 is disposed on the gate insulating layer 112. The gate electrode 122 is disposed on the gate insulating layer 112 so as to overlap a channel region of the active layer 121. The gate electrode 122 may be any one of various metal materials, for example, any one of molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

The interlayer insulating layer 113 is disposed on the gate electrode 122. The interlayer insulating layer 113 may be formed as a single layer of an inorganic material such as silicon nitride (SiNx) or silicon oxide (SiOx) or a multiple layer of an inorganic material such as silicon nitride (SiNx) and/or silicon oxide (SiOx), but it is not limited thereto. In the interlayer insulating layer 113, a contact hole through which the source electrode 123 and the drain electrode 124 are in contact with the source region and the drain region of the active layer 121, respectively, is formed.

The source electrode 123 and the drain electrode 124 are disposed on the interlayer insulating layer 113. The source electrode 123 and the drain electrode 124 are disposed on the same layer to be spaced apart from each other. The source electrode 123 and the drain electrode 124 are electrically connected to the active layer 121 through the contact holes of the gate insulating layer 112 and the interlayer insulating layer 113. The source electrode 123 and the drain electrode 124 may be any one of various metal materials such as molybdenum (Mo), aluminum (Al), chrome (Cr), gold (Au), titanium (Ti), nickel (Ni), neodymium (Nd), and copper (Cu) or an alloy of two or more of them, or a multiple layer thereof, but the present disclosure is not limited thereto.

In FIGS. 2 and 4, only a driving transistor 120, among various transistors included in the display apparatus 100, is illustrated, but other transistors such as a switching transistor may also be disposed.

The first over coating layer 130 is disposed on the interlayer insulating layer 113 and the transistor 120. The first over coating layer 130 is an insulating layer which protects the transistor 120 and planarizes an upper portion of the transistor 120. A contact hole which exposes the source electrode 123 of the transistor 120 is formed on the first over coating layer 130. Even though in FIGS. 2 and 4, it is illustrated that a contact hole which exposes the source electrode 123 is formed on the first over coating layer 130, it is not limited thereto. For example, a contact hole which exposes the drain electrode 124 may be formed on the first over coating layer 130.

The first over coating layer 130 may be formed of one of acrylic-based resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

In the meantime, a passivation layer which covers the interlayer insulating layer 113 and the transistor 120 may be further disposed below the first over coating layer 130. The passivation layer may be formed as a single layer of silicon nitride (SiNx) or silicon oxide (SiOx) or a multiple layer of silicon nitride (SiNx) and/or silicon oxide (SiOx), but it is not limited thereto.

The auxiliary electrode 140 is disposed on the first over coating layer 130. The auxiliary electrode 140 may serve to electrically connect the transistor 120 and the light emitting diode 160. The auxiliary electrode 140 is electrically connected to the source electrode 123 of the transistor 120 through a contact hole formed in the first over coating layer 130. The auxiliary electrode 140 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

The second over coating layer 150 is disposed on the first over coating layer 130. The second over coating layer 150 is an insulating layer for planarizing upper portions of the first over coating layer 130 and the auxiliary electrode 140. A contact hole which exposes the auxiliary electrode 140 is formed on the second over coating layer 150.

The second over coating layer 150 may be formed of one of acrylic-based resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The second over coating layer 150 includes a base portion 151 and a plurality of protrusions 152. As illustrated in FIG. 2, the base portion 151 and the plurality of protrusions 152 may be integrally formed. For example, the base portion 151 and the plurality of protrusions 152 may be formed of the same material to be simultaneously formed by the same process, for example, by a mask process, but are not limited thereto.

The base portion 151 is disposed on the first over coating layer 130. Atop surface of the base portion 151 has a surface parallel to the substrate 110. Therefore, a step generated due to components disposed therebelow may be planarized by the base portion 151.

The plurality of protrusions 152 is disposed on the base portion 151. The plurality of protrusions 152 is integrally formed with the base portion 151 to protrude from the base portion 151. Top surfaces of the plurality of protrusions 152 may be smaller than bottom surfaces of the plurality of protrusions 152, but are not limited thereto.

Each of the plurality of protrusions 152 includes a top surface and a side surface. The top surface of the protrusion 152 is a surface located on an uppermost portion of the protrusion 152 and may be a surface substantially parallel to the base portion 151 or the substrate 110. The side surface of the protrusion 152 may be a surface which connects the top surface of the protrusion 152 and the base portion 151. The side surface of the protrusion 152 may be inclined from the top surface of the protrusion 152 toward the base portion 151.

The light emitting diode 160 is disposed on the second over coating layer 150. The light emitting diode 160 includes a first electrode 161 which is electrically connected to the source electrode 123 of the transistor 120, an organic layer 162 disposed on the first electrode 161, and a second electrode 163 formed on the organic layer 162.

The first electrode 161 is disposed so as to correspond to each of the plurality of sub pixels SP. The first electrode 161 is disposed so as to cover the base portion 151 and the plurality of protrusions 152. The first electrode 161 may be disposed along a shape of the base portion 151 and the plurality of protrusions 152 of the over coating layer 150. Specifically, the first electrode 161 may be disposed on the top surface of the base portion 151 in which the protrusion 152 is not disposed and side surfaces of the plurality of protrusions 152. That is, the first electrode 161 is disposed along the shape of the base portion 151 and the protrusions 152. Further, the first electrode 161 may be formed in a partial area of the top surface of the plurality of protrusions 152.

The first electrode 161 may be an anode of the light emitting diode 160. The first electrode 161 is electrically connected to the auxiliary electrode 140 through the contact hole which is formed on the second over coating layer 150. The first electrode 161 may be electrically connected to the source electrode 123 of the transistor 120 through the auxiliary electrode 140. However, the first electrode 161 may be configured to be electrically connected to the drain electrode 124 of the transistor 120 depending on a type of the transistor 120 and a design manner of the driving circuit.

Even though in FIGS. 2 and 4, the first electrode 161 is illustrated as a single layer, the first electrode 161 may be configured as a multilayer. For example, the first electrode 161 may include a reflective layer which reflects light emitted from the organic layer 162 toward the second electrode 163 and a transparent conductive layer which supplies holes to the organic layer 162.

The reflective layer is disposed on the second over coating layer 150 to reflect light emitted from the light emitting diode 160 upwardly. The light generated in the organic layer 162 of the light emitting diode 160 may be emitted not only upwardly, but also laterally. The light which is laterally emitted is directed to the inside of the display apparatus 100 or trapped in the display apparatus 100 due to the total reflection, or further travels to the inside of the display apparatus 100 and then disappears. Therefore, the reflective layer is disposed below the organic layer 162 to cover side portions of the plurality of protrusions 152 to change a traveling direction of the light which is directed to a side portion of the organic layer 162 to a front direction.

The reflective layer may be formed of a metal material such as aluminum (Al), silver (Ag), copper (Cu), and a magnesium-silver alloy (Mg:Ag), but is not limited thereto.

The transparent conductive layer is disposed on the reflective layer. The transparent conductive layer may be formed of a conductive material having a high work function to supply holes to the organic layer 162. For example, the transparent conductive layer may be formed of transparent conductive oxide such as indium tin oxide (ITO), indium zinc oxide (IZO), indium tin zinc oxide (ITZO), zinc oxide (ZnO), and tin oxide (TO), but is not limited thereto.

The bank layer 170 is disposed on the second over coating layer 150 and the first electrode 161. The bank layer 170 is an insulating layer which separates adjacent sub pixels SP. The bank layer 170 is disposed so as to open a part of the first electrode 161 to form an open area and forms a non-open area which covers a part of the first electrode 161 to define the emission area EA and the non-emission area NEA.

The emission area EA may refer to an area in which light is directly generated by the organic layer 162 in each of the plurality of sub pixels SP. The emission area EA is an opening area of the bank layer 170 so that the bank layer 170 is not disposed and the organic layer 162 is disposed directly on the first electrode 161 to generate light. The emission area EA may be divided into an emission area of a red sub pixel SPR, an emission area of a blue sub pixel SPB, and an emission area of a green sub pixel SPG.

The non-emission area NEA may refer to an area in which the light is not directly generated. The non-emission area NEA is a non-opening area of the bank layer 170 so that the bank layer 170 is disposed between the first electrode 161 and the organic layer 162 to block direct generation of light.

The non-emission area NEA may include a reflection area. Here, the reflection area is an area corresponding to a side surface of the bank layer 170 in which the first electrode 161 is disposed. In the reflection area, the reflective layer of the first electrode 161 formed on the side portion of the protrusion 152 serves as a side mirror so that some of light which may be trapped in the display apparatus 100 by the total reflection is extracted to the outside of the display apparatus 100. The reflection area may be divided into a reflection area of a red sub pixel SPR, a reflection area of a blue sub pixel SPB, and a reflection area of a green sub pixel SPG.

The bank 170 may be formed of an inorganic material. For example, the bank layer 170 may be formed of a single layer of silicon nitride (SiNx) or silicon oxide (SiOx) or a multiple layer of silicon nitride (SiNx) and/or silicon oxide (SiOx). However, it is not limited thereto and the bank 170 may be formed of an organic material.

The organic layer 162 is disposed on the first electrode 161 and the bank layer 170. For example, the organic layer 162 is disposed on the first electrode 161 in the emission area EA and is disposed on the bank layer 170 in the non-emission area NEA. The organic layer 162 may be disposed along the shapes of the first electrode 161 and the bank layer 170. The organic layer 162 includes an emission layer and a common layer.

The emission layer is an organic layer which emits light with a specific color. Different emission layers may be disposed in the plurality of sub pixels SP or the same emission layer may be disposed in all the plurality of sub pixels SP. For example, when different emission layers are disposed in the plurality of sub pixels SP, a red emission layer is disposed in a red sub pixel SPR, a green emission layer is disposed in the green sub pixel SPG, and a blue emission layer may be disposed in the blue sub pixel SPB. When the same emission layer is disposed in all the plurality of sub pixels SP, light from the emission layer may be converted to various color light through a separate light conversion layer and a color filter.

The common layer is an organic layer which is disposed to improve luminous efficiency of the emission layer. The common layer may be formed as the same layer over the plurality of sub pixels SP. That is, the common layers of the plurality of sub pixels SP are simultaneously formed with the same material by the same process. The common layer may include a hole injection layer, a hole transport layer, an electron transport layer, an electron injection layer, and a charge generation layer, but is not limited thereto.

The second electrode 163 is disposed on the organic layer 162. The second electrode 163 may be disposed along the shape of the organic layer 162. The second electrode 163 supplies electrons to the organic layer 162 so that the second electrode may be formed of a conductive material having a low work function. The second electrode 163 may be a cathode of the light emitting diode 160. The second electrode 163 may be formed of a transparent conductive material such as indium tin oxide (ITO) or indium zinc oxide (IZO), or a metal alloy such as MgAg or a ytterbium (Yb) alloy and may further include a metal doping layer, but is not limited thereto. In the meantime, even though it is not illustrated in the drawing, the second electrode 163 is electrically connected to a low potential power line to be supplied with a low potential power signal.

An encapsulation unit 180 may be formed on the light emitting diode 160 to protect the light emitting diode 160 which is vulnerable to moisture so as not to be exposed to the moisture. The encapsulation unit 180 may block the oxygen and moisture from penetrating into the light emitting display apparatus 100 from the outside. For example, when the light emitting display apparatus 100 is exposed to the moisture or oxygen, a pixel shrink phenomenon that the emission area is shrunk occurs or a dead pixel in the emission area is generated. Therefore, the encapsulation unit 180 blocks the oxygen and moisture to protect the light emitting display apparatus 100. For example, the encapsulation unit 180 may have a structure in which inorganic layers and organic layers are alternately laminated, but is not limited thereto.

Referring to FIGS. 2 and 4, the encapsulation unit 180 includes a first encapsulation layer 181, a foreign material cover layer 182, and a second encapsulation layer 183.

The first encapsulation layer 181 is disposed on the second electrode 163 to suppress the permeation of the moisture or oxygen. The first encapsulation layer 181 may be formed of an inorganic material such as silicon nitride (SiNx), silicon oxy nitride (SiNxOy), or aluminum oxide (AlyOz), but is not limited thereto. The first encapsulation layer 181 may be formed of a material having a refractive index higher than that of the foreign material cover layer 182.

The foreign material cover layer 182 is disposed on the first encapsulation layer 181 to planarize the surface. Further, the foreign material cover layer 182 may cover foreign materials or particles which may be generated during a manufacturing process. The foreign material cover layer 182 may be formed of an organic material, such as silicon oxy carbon (SiOxCz), acryl or epoxy-based resin, but is not limited thereto.

The second encapsulation layer 183 is disposed on the foreign material cover layer 182 and may suppress the permeation of the moisture or oxygen, like the first encapsulation layer 181. The second encapsulation layer 183 may be formed of an inorganic material such as silicon nitride (SiNx), silicon oxynitride (SiNxOy), silicon oxide (SiOx), or aluminum oxide (AlyOz), but is not limited thereto. The second encapsulation layer 183 may be formed of the same material as the first encapsulation layer 181 or formed of a different material from the first encapsulation layer 181.

Referring to FIGS. 2 and 4, the black matrix BM is disposed on the encapsulation unit 180. The black matrix BM is disposed between the plurality of sub pixels SP which emits light with different wavelength bands to reduce color mixture between the sub pixels SP. For example, the black matrix BM may be formed of chrome (Cr) or other opaque metal film, or resin, but is not limited thereto.

Referring to FIGS. 2 and 4, the color filter CF is disposed on the encapsulation unit 180 and the black matrix BM. The color filter CF may be disposed so as to overlap the first electrode 161 which is exposed by the bank layer 170. That is, the color filter CF is disposed so as to overlap the entire area of the first electrode 161 which is exposed by the bank layer 170, that is, an opening area to be disposed to overlap the entire area of the emission area EA.

The color filter CF may include a red color filter CFR overlapping the emission area of the red sub pixel SPR, a green color filter CFG overlapping the emission area of the green sub pixel SPG, and a blue color filter CFB overlapping the emission area of the blue sub pixel SPB. Further, the red color filter CFR overlaps the entire emission area of the red sub pixel SPR, the green color filter CFG overlaps the entire emission area of the green sub pixel SPG, and the blue color filter CFB may overlap the entire emission area of the blue sub pixel SPB.

The color filter CF may be formed by dispersing a dye which absorbs light of a specific wavelength band into a base resin. However, it is not limited thereto and the color filter CF may be implemented by various materials. The color filter CF may transmit only light having a specific wavelength band, but blocks light having an undesired wavelength band so as not to be transmitted so that an amount of light which passes through the color filter CF to be extracted is reduced from an amount of light before passing through the color filter CF.

In the meantime, referring to FIG. 6, in the non-active area NA, a spacer SPC, a dam DAM, and a pad PAD are disposed.

The spacer SPC may be disposed above the bank layer 170 in the non-active area NA. The spacer SPC functions to maintain a predetermined gap so that the mask is not in contact with the substrate during a manufacturing process of the organic layer 162 formed of an organic material. Further, the spacer SPC may also function to control the flow of a material for the foreign material cover layer 182 during formation of the foreign material cover layer 182.

In the meantime, even though in the drawing, it is illustrated that the spacer SPC is disposed only in the non-active area NA, the spacer SPC may also be disposed above the bank layer 170 corresponding to an area between the plurality of sub pixels SP in the active area AA. At this time, the organic layer 162 and the second electrode 163 may be disposed on the spacer SPC disposed above the bank layer 170 in the active area AA, but is not limited thereto.

For example, the spacer SPC may be formed of an inorganic insulating material, such as silicon nitride (SiNx) or silicon oxide (SiOx), or an organic insulating material, such as benzocyclobutene-based resin, acrylic-based resin or imide-based resin, but is not limited thereto. Further, the spacer SPC is integrally formed with the bank 170 with the same material, but is not limited thereto.

The dam DAM is disposed in the non-active area NA to block the flow of the foreign material cover layer 182 which is formed of an organic material, among components which configures the encapsulation unit 180. The external dam DAM is disposed so as to enclose all the outer peripheries of the active area AA in the non-active area NA. In the meantime, a plurality of dams DAM is disposed so as to enclose outer peripheries of the active area AA, but is not limited thereto.

The pad PAD is disposed at the outer periphery of the dam DAM in the non-active area NA extending from one side of the active area AA. The pad PAD is connected to the driving IC and the flexible film to supply a signal to drive the plurality of sub pixels SP. For example, the pad PAD is formed on the same layer as the auxiliary electrode 140 of the active area AA and is formed of the same material as the auxiliary electrode 140, but is not limited thereto.

In the meantime, referring to FIGS. 3A, 3B, 5A, and 5B, each of the first sub pixel SP1 and the second sub pixel SP2 includes an emission area EA and a non-emission area NEA. For example, the emission area EA includes a first emission area EA1 and a second emission area EA2 and the non-emission area NEA includes a first non-emission area NEA1 and a second non-emission area NEA2. For example, the first emission area EA1, the first non-emission area NEA1, the second emission area EA2, and the second non-emission area NEA2 are defined by the bank 170.

The first emission area EA1 corresponds to an area in which the first electrode 161 is exposed from the bank layer 170. The first emission area EA1 may refer to an area in which light is substantially generated by the organic layer 162 in each of the first sub pixel SP1 and the second sub pixel SP2. In the first emission area EA1, the bank 170 is not disposed and the organic layer 162 is located directly on the first electrode 161 to generate light.

The first non-emission area NEA1 encloses the first emission area EA1 and may correspond to an area where the bank 170 is disposed on the first electrode 161 on the base portion 151. At this time, the first non-emission area NEA1 may correspond to an area which does not overlap the side surface of the protrusion 152. When the display apparatus 100 is on, the first non-emission area NEA1 is in a black state or may have a luminance lower than those of the first emission area EA1 and the second emission area EA2 due to light incident from at least one of the first emission area EA1 and the second emission area EA2.

The second emission area EA2 encloses the first non-emission area NEA1 and corresponds to the side surface of the protrusion 152. The second emission area EA2 may be an area in which some of light emitted from the organic layer 162 is reflected by the first electrode 161 disposed on the inclined side surface of the protrusion 152 to be extracted to the outside of the display apparatus 100. Further, the luminance of the second emission area EA2 is lower than the luminance of the first emission area EA1, but is not limited thereto.

The second non-emission area NEA2 encloses the second emission area EA2 and may correspond to a flat top surface of the protrusion 152. The second non-emission area NEA2 may be an area in which components for driving the emission area EA are disposed.

When the display apparatus 100 is on, the second non-emission area NEA2 is in a black state or has a luminance lower than those of the first emission area EA1 and the second emission area EA2 due to light incident from an emission unit of at least one of the first emission area EA1 and the second emission area EA2. Further, when the luminance of the second non-emission area NEA2 is lower than the luminance of the first emission area EA1 and the second emission area EA2, the luminance of the first non-emission area NEA1 may be higher than the luminance of the second non-emission area NEA2, but is not limited thereto.

Hereinafter, the first sub pixel SP1 disposed in the first area A1 and the second sub pixel SP2 disposed in the second area A2 will be described in more detail with reference to FIGS. 2 to 3B and 4 to 5C.

Referring to FIGS. 2 and 3A, a side surface of the protrusion 152 is disposed on the base portion 151 with an inclination angle of a first angle θ1 in the first sub pixel SP1. At this time, for example, the first angle θ1 may have a relatively large inclination angle of 45° to 60°.

Referring to FIGS. 4 and 5A, a side surface of the protrusion 152 may be disposed on the base portion 151 with an inclination angle of a second angle θ2 in the second sub pixel SP2. At this time, for example, the second angle θ2 may have a relatively small inclination angle of 30° to 45°.

In the meantime, referring to FIGS. 2, 3A, 4, and 5A together, the inclination angle θ1 of the side surface of the protrusion 152 of the first sub pixel SP1 is larger than the inclination angle θ2 of the side surface of the protrusion 152 of the second sub pixel SP2. For example, in each of the first sub pixel SP1 and the second sub pixel SP2, the protrusion 152 protrudes with the same height from the base portion 151 and a length (i.e., an extending length in a direction parallel to the substrate 110) of a side surface of the protrusion 152 disposed in the first sub pixel SP1 may be shorter than a length (i.e., an extending length in a direction parallel to the substrate 110) of a side surface of the protrusion 152 disposed in the second sub pixel SP2.

For example, referring to FIGS. 3A and 5A together, a lower width A of an area defined by the protrusions 152 corresponding to one light emitting diode 160 (for example, the first electrode 161) in the first sub pixel SP1 may be larger than a lower width A′ of an area defined by the protrusions 152 corresponding to one light emitting diode 160 (for example, the first electrode 161) in the second sub pixel SP2. Further, an upper width B of an area defined by the protrusions 152 corresponding to one light emitting diode 160 (for example, the first electrode 161) in the first sub pixel SP1 may be smaller than an upper width B′ of an area defined by the protrusions 152 corresponding to one light emitting diode 160 (for example, the first electrode 161) in the second sub pixel SP2. With regard to a length (i.e., an extending length in a direction parallel to the substrate 110) (B-A, B′-A′) of the side surface of the protrusion 152, which is a difference of the upper width B, B′ and the lower width A, A′ of the area defined by the protrusions 152 corresponding to one light emitting diode 160, the length (i.e., an extending length in a direction parallel to the substrate 110) B-A of the side surface of the protrusion 152 of the first sub pixel SP1 may be shorter than the length (i.e., an extending length in a direction parallel to the substrate 110) B′-A′ of the side surface of the protrusion 152 of the second sub pixel SP2. Therefore, in each of the first sub pixel SP1 and the second sub pixel SP2, when the protrusion 152 protrudes with the same height from the base portion 151, the inclination angle θ1 of the side surface of the protrusion 152 of the first sub pixel SP1 may be larger than the inclination angle θ2 of side surface of the protrusion 152 of the second sub pixel SP2, but the present disclosure is not limited thereto.

At this time, in order to make the inclination angle of the protrusion 152 of the second sub pixel SP2 smaller than the inclination angle of the protrusion 152 of the first sub pixel SP1, for example, in a mask used for the process of forming the protrusion 152 of the first sub pixel SP1 and the second sub pixel SP2 by removing the top surface of the second over coating layer 150, a slit mask may be applied only to a portion corresponding to the protrusion 152 of the second sub pixel SP2. Therefore, diffraction occurs by a plurality of slits disposed in the slit mask so that light may more widely spread during an exposure process for removing the top surface of the second over coating layer 150. Therefore, the top surface of the second over coating layer 150 in a portion corresponding to the protrusion 152 of the second sub pixel SP2 may be removed to be wider than that in the portion corresponding to the first sub pixel SP1 and the inclination angle of the protrusion 152 of the second sub pixel SP2 may be smaller than the inclination angle of the protrusion 152 of the first sub pixel SP1, but the present disclosure is not limited thereto. Further, a slit mask is partially configured in one mask as described above so that the protrusion 152 of the second over coating layer 150 having inclined surfaces with different angles may be implemented using one same mask. Therefore, an effect of reducing the number of masks and the number of processing processes may be achieved.

In the meantime, referring to FIGS. 3A and 5A together, a size of the light emitting diode 160 of the first sub pixel SP1 may be smaller than a size of the light emitting diode 160 of the second sub pixel SP2. A size of the light emitting diode 160 of the second sub pixel SP2 may be larger than a size of the light emitting diode 160 of the first sub pixel SP1. For example, an upper width C of an area defined by the banks 170 corresponding to one light emitting diode 160 (for example, the first electrode 161) in the first sub pixel SP1 may be smaller than an upper width C′ of an area defined by the banks 170 corresponding to one light emitting diode 160 (for example, the first electrode 161) in the second sub pixel SP2. A lower width D of an area defined by the banks 170 corresponding to one light emitting diode 160 (for example, the first electrode 161) in the first sub pixel SP1 may be larger than a lower width D′ of an area defined by the banks 170 corresponding to one light emitting diode 160 (for example, the first electrode 161) in the second sub pixel SP2, but the present disclosure is not limited thereto.

Further, a width E of an area defined by the black matrixes BM corresponding to one light emitting diode 160 (for example, the first electrode 161) in the first sub pixel SP1 is smaller than or equal to a width E′ of an area defined by the black matrixes BM corresponding to one light emitting diode 160 (for example, the first electrode 161) in the second sub pixel SP2. At this time, with regard to the difference of the widths E and E′ of the area defined by the black matrixes BM corresponding to one light emitting diode 160 and the upper widths C and C′ of the area defined by the banks 170 corresponding to one light emitting diode 160, the difference in the first sub pixel SP1 may be larger than the difference in the second sub pixel SP2. That is, the difference of the width E of the area defined by the black matrixes BM corresponding to one light emitting diode 160 and the upper width C of the area defined by the banks 170 corresponding to one light emitting diode 160 in the first sub pixel SP1 may be larger than the difference of the width E′ of the area defined by the black matrixes BM corresponding to one light emitting diode 160 and the upper width C′ of the area defined by the banks 170 corresponding to one light emitting diode 160 in the second sub pixel SP2, but the present disclosure is not limited thereto.

In the meantime, referring to FIGS. 3B and 5B together, in the plan view, an area of the first emission area EA1 of the plurality of first sub pixels SP1 may be larger than an area of the first emission area EA1 of the plurality of second sub pixels SP2. Further, in the plan view, the area of the second emission area EA2 of the plurality of first sub pixels SP1 may be smaller than the area of the second emission area EA2 of the plurality of second sub pixels SP2. That is, the inclination angle θ2 of the protrusion 152 of the second sub pixel SP2 is smaller than the inclination angle θ1 of the protrusion 152 of the first sub pixel SP1. Accordingly, a length (i.e., an extending length in a direction parallel to the substrate 110) of the side surface of the protrusion 152 of the second sub pixel SP2, that is, the area of the second emission area EA2 of the second sub pixel SP2 may be increased. At this time, an area in which the first electrode 161 is exposed from the bank 170 in the second sub pixel, that is, the area of the first emission area EA1 of the second sub pixel may be reduced.

At this time, referring to FIGS. 3B and 5B together, in the plan view, an area of the emission area EA of the second sub pixels SP2 may be larger than an area of the emission area EA of the first sub pixels SP1. That is, an area enclosed by a boundary line of the second emission area EA2 and the second non-emission area NEA2 of the second sub pixel SP2 is larger than an area enclosed by a boundary line of the second emission area EA2 and the second non-emission area NEA2 of the first sub pixel SP1, but the present disclosure is not limited thereto.

In the meantime, referring to FIGS. 2 to 3B, among light emitted from the first emission area EA1 of the first sub pixel SP1, first light L1 which is reflected by the first electrode 161 disposed on the side surface of the protrusion 152 may be configured to be reflected toward the inside of the first sub pixel SP1. Accordingly, in the first area A1, an amount of light extracted to the front surface, among light emitted from the first sub pixel SP1, may be improved.

Further, referring to FIGS. 4 to 5C, among light emitted from the first emission area EA1 of the second sub pixel SP2, second light L2 which is reflected by the first electrode 161 disposed on the side surface of the protrusion 152 may be configured to be reflected toward the outside of the second sub pixel SP2. Accordingly, in the second area A2, a viewing angle of light emitted from the second sub pixel SP2 may be improved to a wider viewing angle.

In the meantime, referring to FIG. 5C, a second area A2 of the substrate 110 in which the second sub pixel SP2 is disposed may be inclined while forming a predetermined third angle θ3 with a virtual surface PS which is parallel to the first area A1. That is, the second area is an area which is bent with respect to the first area to be disposed on a curved surface so that as illustrated in FIG. 5C, the second area may be inclined with a predetermined third angle as compared with the first area. Accordingly, the second light L2 which is reflected by the first electrode 161 disposed on the side surface of the protrusion 152 in the second sub pixel SP2 is reflected toward the side surface of the second sub pixel SP2 so that the second light is configured to be directed to the front surface of the display apparatus 100.

In the display apparatus in which a curved portion or a bent portion is disposed on at least one side, among four sides enclosing the flat area, distribution of light emitted from the light emitting diode is directed to the front surface. Accordingly, the distribution of light emitted from the light emitting diode may be directed to the side surface of the display apparatus in the curved portion or the bent portion. Therefore, an amount of light which is extracted to the front surface of the display apparatus, among light emitted from the light emitting diode, is reduced to cause a luminance difference between the curved portion or the bent portion and the flat area.

Further, an optical distance between the first electrode and the second electrode in the curved portion or the bent portion in the front direction is different from an optical distance between the first electrode and the second electrode in the flat area in the front direction. Therefore, there may be an additional problem in that a color coordinate between the curved portion or the bent portion and the flat area is changed.

In the display apparatus 100 according to the example implementation of the present disclosure, the inclination angle θ1 of the side surface of the protrusion 152 of the first sub pixel SP1 of the first area A1 is larger than the inclination angle θ2 of the side surface of the protrusion 152 of the second sub pixel SP2 of the second area A2. Further, a height of the protrusion 152 of the first sub pixel SP1 of the first area A1 is equal to a height of the protrusion 152 of the second sub pixel SP2 of the second area A2. Accordingly, the luminance difference between the first area A1 and the second area A2 may be minimized.

Specifically, the inclination angle θ1 of the side surface of the protrusion 152 of the first sub pixel SP1 of the first area A1 which is the flat area is larger than the inclination angle θ2 of the side surface of the protrusion 152 of the second sub pixel SP2 of the second area A2 which is the curved area. Accordingly, among light emitted from the first emission area EA1 of the first sub pixel SP1, the first light L1 which is reflected by the first electrode 161 disposed on the side surface of the protrusion 152 is configured to be reflected toward the front surface of the first sub pixel SP1. Further, among light emitted from the first emission area EA1 of the second sub pixel SP2, the second light L2 which is reflected by the first electrode 161 disposed on the side surface of the protrusion 152 may be configured to be reflected toward the outside of the second sub pixel SP2. At this time, the second light L2 emitted from the second sub pixel SP2 is reflected toward the side surface of the second sub pixel SP2 to be directed to the front surface of the display apparatus 100 in the second area A2. Therefore, a traveling path of light emitted from the second area A2 which is a curved area is changed to be directed to the front surface of the display apparatus 100 so that an amount of light extracted to the front surface of the display apparatus 100 may be increased and a luminance difference between the first area A1 and the second area A2 may be minimized. Further, the problem of the color coordinate change between the first area A1 and the second area A2 may be minimized. Accordingly, in the display apparatus 100 according to the example implementation of the present disclosure, the inclination angle θ1 of the side surface of the protrusion 152 of the first sub pixel SP1 of the first area A1 is larger than the inclination angle θ2 of the side surface of the protrusion 152 of the second sub pixel SP2 of the second area A2. By doing this, the luminance difference between the first area A1 and the second area A2 may be minimized. Further, the problem of the color coordinate change between the first area A1 and the second area A2 may be minimized to improve a display quality of the display apparatus 100.

The example implementations of the present disclosure can also be described as follows:

According to an aspect of the present disclosure, a display apparatus includes a substrate including a first area in which a plurality of first sub pixels is disposed and a second area which encloses the first area and includes a plurality of second sub pixels disposed therein, an over coating layer which is disposed on the substrate and includes a base portion and a protrusion which protrudes from the base portion and has an inclined side surface, a plurality of first electrodes each of which is disposed in each of the plurality of first sub pixels and the plurality of second sub pixels and is disposed so as to cover the side surface of the protrusion and the base portion, a bank which is disposed on a top surface of the protrusion and the first electrode and exposes a part of the first electrode disposed on the base portion, an organic layer disposed on the plurality of first electrodes and the bank, and a second electrode disposed on the organic layer. An inclination angle of the side surface of the protrusion of the plurality of first sub pixels is larger than an inclination angle of the side surface of the protrusion of the plurality of second sub pixels.

Each of the plurality of first sub pixels and the plurality of second sub pixels may include a first emission area corresponding to an area where the first electrode is exposed from the bank; a first non-emission area which encloses the first emission area and corresponds to an area where the bank is disposed on the first electrode on the base portion; and a second emission area which encloses the first non-emission area and corresponds to the side surface of the protrusion.

In the plan view, an area of the second emission area of the plurality of first sub pixels may be smaller than an area of the second emission area of the plurality of second sub pixels.

An area of the first emission area of the plurality of first sub pixels is larger than an area of the first emission area of the plurality of second sub pixels.

Each of the plurality of first sub pixels and the plurality of second sub pixels may further include a second non-emission area which corresponds to a top surface of the protrusion and is disposed so as to enclose the second emission area.

In the plan view, a size of an area enclosed by a boundary line of the second emission area and the second non-emission area of the first sub pixel may be smaller than a size of an area enclosed by a boundary line of the second emission area and the second non-emission area of the second sub pixel.

An extending length in a direction parallel to the substrate of the side surface of the protrusion disposed in the plurality of first sub pixels may be shorter than an extending length in the direction parallel to the substrate of the side surface of the protrusion disposed in the plurality of second sub pixels.

A lower width of an area defined by the protrusions corresponding to a first electrode in each of the plurality of first sub pixels may be larger than a lower width of an area defined by the protrusions corresponding to a first electrode in each of the plurality of second sub pixels.

An upper width of an area defined by the protrusions corresponding to a first electrode in each of the plurality of first sub pixels may be smaller than an upper width of an area defined by the protrusions corresponding to a first electrode in each of the plurality of second sub pixels.

An upper width of an area defined by the banks corresponding to a first electrode in each of the plurality of first sub pixels may be smaller than an upper width of an area defined by the banks corresponding to a first electrode in each of the plurality of second sub pixels.

A lower width of an area defined by the banks corresponding to a first electrode in each of the plurality of first sub pixels may be larger than a lower width of an area defined by the banks corresponding to a first electrode in each of the plurality of second sub pixels.

The first area may be a flat area and the second area may be a curved area in which the further from the first area, the larger the slope of the second area.

According to another aspect of the present disclosure, a display apparatus includes a substrate including a first area in which a plurality of first sub pixels is disposed and a second area which encloses the first area and includes a plurality of second sub pixels disposed therein, an over coating layer which is disposed on the substrate and includes a base portion and a protrusion which protrudes from the base portion and has an inclined side surface, a plurality of first electrodes each of which is disposed in each of the plurality of first sub pixels and the plurality of second sub pixels and is disposed so as to cover the side surface of the protrusion and the base portion, a bank which is disposed on the protrusion and the first electrode and exposes a part of the first electrode disposed on the base portion, an organic layer disposed on the plurality of first electrodes and the bank, and a second electrode disposed on the organic layer. The protrusion protrudes with the same height from the base portion in each of the plurality of first sub pixels and the plurality of second sub pixels and an extending length in a direction parallel to the substrate of the side surface of the protrusion disposed in the plurality of first sub pixels is shorter than an extending length in the direction parallel to the substrate of the side surface of the protrusion disposed in the plurality of second sub pixels.

Each of the plurality of first sub pixels and the plurality of second sub pixels may include a first emission area corresponding to an area where the first electrode is exposed from the bank; a first non-emission area which encloses the first emission area and corresponds to an area where the bank is disposed on the first electrode on the base portion; and a second emission area which encloses the first non-emission area and corresponds to the side surface of the protrusion.

In the plan view, an area of the second emission area of the plurality of first sub pixels may be smaller than an area of the second emission area of the plurality of second sub pixels.

Each of the plurality of first sub pixels and the plurality of second sub pixels may further include a second non-emission area which corresponds to a top surface of the protrusion and is disposed so as to enclose the second emission area.

In the plan view, a size of an area enclosed by a boundary line of the second emission area and the second non-emission area of the first sub pixel may be smaller than a size of an area enclosed by a boundary line of the second emission area and the second non-emission area of the second sub pixel.

The first electrode of the plurality of first sub pixels may be disposed to form a first angle from a top surface of the base portion.

The first electrode of the plurality of second sub pixels may be disposed to form a second angle which is smaller than the first angle from the top surface of the base portion.

A lower width of an area defined by the protrusions corresponding to a first electrode in each of the plurality of first sub pixels may be larger than a lower width of an area defined by the protrusions corresponding to a first electrode in each of the plurality of second sub pixels.

An upper width of an area defined by the protrusions corresponding to a first electrode in each of the plurality of first sub pixels may be smaller than an upper width of an area defined by the protrusions corresponding to a first electrode in each of the plurality of second sub pixels.

An upper width of an area defined by the banks corresponding to a first electrode in each of the plurality of first sub pixels may be smaller than an upper width of an area defined by the banks corresponding to a first electrode in each of the plurality of second sub pixels.

A lower width of an area defined by the banks corresponding to a first electrode in each of the plurality of first sub pixels may be larger than a lower width of an area defined by the banks corresponding to a first electrode in each of the plurality of second sub pixels.

The first area may be a flat area and the second area may be a curved area in which the further from the first area, the larger the slope of the second area.

Although the example implementations of the present disclosure have been described in detail with reference to the accompanying drawings, the present disclosure is not limited thereto and may be embodied in many different forms without departing from the technical concept of the present disclosure. Therefore, the example implementations of the present disclosure are provided for illustrative purposes only but not intended to limit the technical concept of the present disclosure. The scope of the technical concept of the present disclosure is not limited thereto. Therefore, it should be understood that the above-described example implementations are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus, comprising:
a substrate including (i) a first area in which a plurality of first sub pixels is disposed and (ii) a second area disposed outside a periphery of the first area and including a plurality of second sub pixels;
an over coating layer which is disposed on the substrate and includes a base portion and a plurality of protrusions which protrude from the base portion, each of the plurality of protrusions having an inclined side surface;
a plurality of first electrodes each of which is disposed in a respective sub-pixel among the plurality of first sub pixels and the plurality of second sub pixels, wherein each first electrode among the plurality of first electrodes is disposed so as to cover the inclined side surface of a respective protrusion among the plurality of protrusions and to cover a part of the base portion adjacent to the respective protrusion; and
a bank layer which is disposed on a top surface of the plurality of protrusions and the plurality of first electrodes and exposes a part of each of the plurality of first electrodes disposed on the base portion,
wherein an inclination angle of the inclined side surface of the protrusion of each of the plurality of first sub pixels is larger than an inclination angle of the inclined side surface of the protrusion of each of the plurality of second sub pixels.

2. The display apparatus according to claim 1, wherein the each sub-pixel among the plurality of first sub pixels and the plurality of second sub pixels includes:
a first emission area corresponding to an area where a respective first electrode among the plurality of first electrodes is exposed from the bank layer;
a first non-emission area outside a periphery of the first emission area and corresponding to an area where the bank layer is disposed on the respective first electrode on the base portion; and
a second emission area which outside a periphery of the first non-emission area and corresponding to the side surface of the respective protrusion among the plurality of protrusions, and
in a plan view, an area of the second emission area of each of the plurality of first sub pixels is smaller than an area of the second emission area of each of the plurality of second sub pixels.

3. The display apparatus according to claim 2, wherein an area of the first emission area of each of the plurality of first sub pixels is larger than an area of the first emission area of each of the plurality of second sub pixels.

4. The display apparatus according to claim 2, wherein the each sub-pixel among the plurality of first sub pixels and the plurality of second sub pixels further includes a second non-emission area which corresponds to a top surface of the respective protrusion and is disposed outside a periphery of the second emission area.

5. The display apparatus according to claim 4, wherein in the plan view, a size of an area enclosed by a boundary line of the second emission area and the second non-emission area of each of the plurality of first sub pixels is smaller than a size of an area enclosed by a boundary line of the second emission area and the second non-emission area of each of the plurality of second sub pixels.

6. The display apparatus according to claim 1, wherein an extending length in a direction parallel to the substrate of the inclined side surface of the protrusion disposed in each of the plurality of first sub pixels is shorter than an extending length in the direction parallel to the substrate of the inclined side surface of the protrusion disposed in each of the plurality of second sub pixels.

7. The display apparatus according to claim 1, wherein a lower width of an area defined between adjacent protrusions corresponding to the first electrode in each of the plurality of first sub pixels is larger than a lower width of an area defined between adjacent protrusions corresponding to the first electrode in each of the plurality of second sub pixels; and
an upper width of the area defined between the adjacent protrusions corresponding to the first electrode in each of the plurality of first sub pixels is smaller than an upper width of the area defined between the adjacent protrusions corresponding to a first electrode in each of the plurality of second sub pixels.

8. The display apparatus according to claim 1, wherein the bank layer includes a plurality of banks, and
wherein an upper width of an area defined between adjacent banks corresponding to the first electrode in each of the plurality of first sub pixels is smaller than an upper width of the area defined between the adjacent banks corresponding to the first electrode in each of the plurality of second sub pixels; and
a lower width of the area defined between the adjacent banks corresponding to the first electrode in each of the plurality of first sub pixels is larger than a lower width of the area defined between the adjacent banks corresponding to the first electrode in each of the plurality of second sub pixels.

9. The display apparatus according to claim 1, wherein the first area is a flat area and the second area is a curved area in which a slope of the second area increases with increasing distance from the first area.

10. The display apparatus according to claim 1, further comprising:
an organic layer disposed on the plurality of first electrodes and the bank layer.

11. The display apparatus according to claim 10, further comprising:
a second electrode disposed on the organic layer.

12. A display apparatus, comprising:
a substrate including (i) a first area in which a plurality of first sub pixels is disposed and (ii) a second area disposed outside a periphery of the first area and including a plurality of second sub pixels;
an over coating layer which is disposed on the substrate and includes a base portion and a plurality of protrusions which protrude from the base portion, each of the plurality of protrusions having an inclined side surface;
a plurality of first electrodes each of which is disposed in a respective sub-pixel among the plurality of first sub pixels and the plurality of second sub pixels, wherein each first electrode among the plurality of first electrodes is disposed so as to cover the inclined side surface of a respective protrusion among the plurality of protrusions and to cover a part of the base portion adjacent to the respective protrusion;
a bank layer which is disposed on the plurality of protrusions and the plurality of first electrodes and exposes a part of each of the plurality of first electrodes disposed on the base portion,
wherein the each of the plurality of protrusions protrudes with a same height from the base portion in the each sub-pixel of the plurality of first sub pixels and the plurality of second sub pixels and
wherein an extending length in a direction parallel to the substrate of the inclined side surface of the protrusion disposed in each of the plurality of first sub pixels is shorter than an extending length in the direction parallel to the substrate of the inclined side surface of the protrusion disposed in each of the plurality of second sub pixels.

13. The display apparatus according to claim 12, wherein the each sub-pixel among the plurality of first sub pixels and the plurality of second sub pixels includes:
a first emission area corresponding to an area where a respective first electrode among the plurality of first electrodes is exposed from the bank layer;
a first non-emission area outside a periphery of the first emission area and corresponding to an area where the bank layer is disposed on the respective first electrode on the base portion; and
a second emission area which outside a periphery of the first non-emission area and corresponding to the side surface of the respective protrusion among the plurality of protrusions, and
in a plan view, an area of the second emission area of each of the plurality of first sub pixels is smaller than an area of the second emission area of each of the plurality of second sub pixels.

14. The display apparatus according to claim 13, wherein the each sub-pixel among the plurality of first sub pixels and the plurality of second sub pixels further includes a second non-emission area which corresponds to a top surface of the respective protrusion and is disposed outside a periphery of the second emission area, and
wherein in the plan view, a size of an area enclosed by a boundary line of the second emission area and the second non-emission area of each of the plurality of first sub pixels is smaller than a size of an area enclosed by a boundary line of the second emission area and the second non-emission area of each of the plurality of second sub pixels.

15. The display apparatus according to claim 12, wherein the first electrode of each of the plurality of first sub pixels is disposed to form a first angle relative to a top surface of the base portion, and
wherein the first electrode of each of the plurality of second sub pixels is disposed to form a second angle, relative to the top surface of the base portion, which is smaller than the first angle.

16. The display apparatus according to claim 12, wherein a lower width of an area defined between adjacent protrusions corresponding to the first electrode in each of the plurality of first sub pixels is larger than a lower width of an area defined between adjacent protrusions corresponding to the first electrode in each of the plurality of second sub pixels; and
an upper width of the area defined between the adjacent protrusions corresponding to the first electrode in each of the plurality of first sub pixels is smaller than an upper width of the area defined between the adjacent protrusions corresponding to a first electrode in each of the plurality of second sub pixels.

17. The display apparatus according to claim 12, wherein the bank layer includes a plurality of banks, and
wherein an upper width of an area defined between adjacent banks corresponding to the first electrode in each of the plurality of first sub pixels is smaller than an upper width of the area defined between the adjacent banks corresponding to the first electrode in each of the plurality of second sub pixels; and
a lower width of the area defined between the adjacent banks corresponding to the first electrode in each of the plurality of first sub pixels is larger than a lower width of the area defined between the adjacent banks corresponding to the first electrode in each of the plurality of second sub pixels.

18. The display apparatus according to claim 12, wherein the first area is a flat area and the second area is a curved area in which a slope of the second area increases with increasing distance from the first area.

19. The display apparatus according to claim 12, further comprising:
an organic layer disposed on the plurality of first electrodes and the bank layer.

20. The display apparatus according to claim 19, further comprising:
a second electrode disposed on the organic layer.
